(19) United States
(12) Patent Application Publication
(10) Pub. No.: US 2025/0076232 A1
(43) Pub. Date: Mar. 6, 2025

(54) Inspection Apparatus and Mounting Base

(71) Applicant: Tokyo Electron Limited, Tokyo (JP)

(72) Inventors: Shigeru KASAI, Yamanashi (JP); Naoki AKIYAMA, Yamanashi (JP); Fumiya TAKASE, Yamanashi (JP); Hiroyuki NAKAYAMA, Yamanashi (JP); Hajime KUMASAKA, Yamanashi (JP)

(21) Appl. No.: 18/950,924

(22) Filed: Nov. 18, 2024

Related U.S. Application Data
(63) Continuation of application No. PCT/JP2023/018576, filed on May 18, 2023.

(30) Foreign Application Priority Data
Jun. 1, 2022 (JP) 2022-089740
Aug. 2, 2022 (JP) 2022-123255

(51) Int. Cl. G01N 25/72; G01R 31/26; G01R 31/265

(52) U.S. Cl. CPC G01N 25/72; G01R 31/2601; G01R 31/265

(57) ABSTRACT

An inspection apparatus for inspecting an inspection target device is presented. The inspection apparatus comprises a placing table that supports the inspection target object while facing the back surface of the imaging device, and the placing table includes: a ceiling plate made of a light transmitting material and having a placing surface on which the inspection target object is placed, an irradiation part that is disposed at a position facing the inspection target object with the ceiling plate interposed therebetween and that irradiates light toward the inspection target object placed on the placing surface; and a temperature controller configured to adjusts a temperature of the inspection target device of the inspection target object placed on the placing surface.

### CROSS-REFERENCE TO RELATED APPLICATIONS

This application is a bypass continuation application of International Application No. PCT/JP2023/018576 having an international filing date of May 18, 2023 and designating the United States, the International Application being based upon and claiming the benefit of priority from the Japanese Patent Application Nos. 2022-089740 filed on Jun. 1, 2022, and 2022-123255 filed on Aug. 2, 2022, respectively, the entire contents of which are incorporated herein by reference.

### TECHNICAL FIELD

The present disclosure relates to an inspection apparatus and a placing table.

### BACKGROUND

The inspection apparatus of Japanese Laid-open Patent Publication No. 2019-106491 inspects an imaging device formed on an inspection target object by allowing light to be incident on the imaging device and bringing a contact terminal into electrical contact with a wiring layer of the imaging device. In Japanese Laid-open Patent Publication No. 2019-106491, light is incident on the imaging device from the back surface, which is the surface opposite to the surface on which the wiring layer is provided. The inspection apparatus of Japanese Laid-open Patent Publication No. 2019-106491 includes a placing table made of a light transmitting member on which the inspection target object is placed to face the back surface of the imaging device, and a light irradiation mechanism having a plurality of LEDs that are arranged to face the inspection target object with the placing table interposed therebetween and are directed toward the inspection target object.

### SUMMARY

The technique of the present disclosure enables a temperature of an imaging device to be accurately measured without adversely affecting light irradiated to the imaging device in the case of inspecting a backside-illumination type imaging device.

One aspect of the present disclosures relates an inspection apparatus for inspecting an inspection target device. The inspection target device is a backside-illumination type imaging device on which light is incident from a back surface opposite to a side on which a wiring layer is provided, and is formed on an inspection target object. The inspection apparatus comprises a placing table that supports the inspection target object while facing the back surface of the imaging device, and the placing table includes: a ceiling plate made of a light transmitting material and having a placing surface on which the inspection target object is placed, an irradiation part that is disposed at a position facing the inspection target object with the ceiling plate interposed therebetween and that irradiates light toward the inspection target object placed on the placing surface; and a temperature controller configured to adjusts a temperature of the inspection target device of the inspection target object placed on the placing surface. A pattern made of a metal material and having a thickness that transmits light is formed on at least one of the placing surface of the ceiling plate or a surface opposite to the placing surface.

### BRIEF DESCRIPTION OF THE DRAWINGS

FIG. 1 is a plan view schematically showing a configuration of a substrate as an inspection target object on which a backside-illumination imaging device is formed.

FIG. 2 is a cross-sectional view schematically showing a configuration of a backside-illumination type imaging device.

FIG. 3 is a perspective view schematically showing a configuration of a prober as an inspection apparatus according to an embodiment.

FIG. 4 is a front view schematically showing the configuration of the prober as the inspection apparatus according to the embodiment.

FIG. 5 is a cross-sectional view schematically showing a configuration of the stage.

FIG. 6 is a top view of a ceiling plate.

FIG. 7 shows a configuration of a circuit for measuring a temperature of a sensor pattern.

FIG. 8 shows another example of connection between the sensor pattern and a current source.

FIG. 9 is cross-sectional view schematically showing a configuration of a stage of a prober serving as an inspection apparatus according to a second embodiment.

FIG. 10 shows a configuration of a circuit related to a sensor pattern in the second embodiment.

FIG. 11 shows another example of an irradiation part.

FIG. 12 is a cross-sectional view schematically showing a configuration of a stage of a prober serving as an inspection apparatus according to a third embodiment.

### DETAILED DESCRIPTION

In a semiconductor manufacturing process, a plurality of semiconductor devices having a predetermined circuit pattern are formed on a substrate such as a semiconductor wafer (hereinafter, referred to as “wafer”). The electrical characteristics of the formed semiconductor devices are inspected to classify them into non-defective products and defective products. The semiconductor devices are inspected using an inspection apparatus referred to as a prober or the like before the substrate is divided into semiconductor devices.

In the inspection apparatus, a probe card having a plurality of probes, which are needle-shaped contact terminals, is disposed above a placing table that supports the substrate. During the inspection, the probe card and the wafer on the placing table become close to each other, and the probes of the probe card are brought into contact with electrodes of the semiconductor devices formed on the substrate. In that state, an electrical signal is supplied from a test head disposed above the probe card to the semiconductor devices through the probes. Then, based on the electrical signal received by the test head from the semiconductor devices through the probes, the corresponding semiconductor devices are classified into defective products or non-defective products.

When the semiconductor device to be inspected is an imaging device such as a CMOS sensor or the like, the inspection is performed while irradiating the imaging device with light, unlike other general semiconductor devices.

Further, recently, a backside-illumination type imaging device that receives light incident from the back side opposite to the front side on which a wiring layer is formed has been developed as the imaging device.

In an inspection apparatus for a backside-illumination type imaging device, a placing table supports a substrate while facing the back side of the imaging device. Further, in the inspection apparatus for the backside-illumination type imaging device, the placing table includes a ceiling plate made of a light transmitting material and having a placing surface on which the substrate is placed, and an irradiation part that is disposed below the placing surface and irradiates light toward the substrate placed on the placing surface.

The irradiation part has, e.g., a light guiding plate having a facing surface that faces the substrate with the ceiling plate interposed therebetween, and a light source part that is disposed in a region laterally outside from the light guiding plate and emits light toward the light guiding plate. In the irradiation part, the light guiding plate reflects the light emitted from the light source part and incident from the lateral edge surface of the light guiding plate toward the facing surface, and emits light in a planar shape from the facing surface. Hereinafter, the irradiation part on which light is incident from the lateral edge surface of the light guiding plate as described above is referred to as “side-incidence type irradiation part.”

Further, a temperature controller for adjusting a temperature of the imaging device may be provided at the placing table of the inspection apparatus so that the imaging device is maintained at a predetermined temperature during inspection of a backside-illumination type imaging device. The temperature controller is provided, e.g., below the side-incidence type irradiation part below the ceiling plate, and heats and cools the substrate via the ceiling plate. For the above-described temperature control, it is necessary to measure the temperature of the imaging device.

However, if a temperature sensor, e.g., a thermocouple, is provided at the placing surface, i.e., the upper surface, of the ceiling plate to measure the temperature of the imaging device, the light from the irradiation part may be blocked by the temperature sensor.

Further, as described above, when the substrate is heated or cooled by a temperature controller disposed below the side-incidence type irradiation part, the temperature sensor may be provided on the bottom surface of the light guiding plate to measure the temperature of the imaging device. However, with this configuration, when the light guiding plate is made of glass or the like, which is inexpensive but has low thermal conductivity, it is difficult to accurately measure the temperature of the imaging device.

Therefore, the technique of the present disclosure enables the temperature of the imaging device to be accurately measured without adversely affecting the light irradiated to the imaging device in the case of inspecting the backside-illumination type imaging device.

Hereinafter, an inspection apparatus and a placing table according to the embodiment will be described with reference to the accompanying drawings. In this specification and the drawings, like reference numerals will be used for like parts having substantially the same functional configuration, and redundant description thereof will be omitted.

In the technique of the present embodiment, an inspection target device is a backside-illumination type imaging device, so that the backside-illumination type imaging device will be described first.

### Backside-Illumination Type Imaging Device

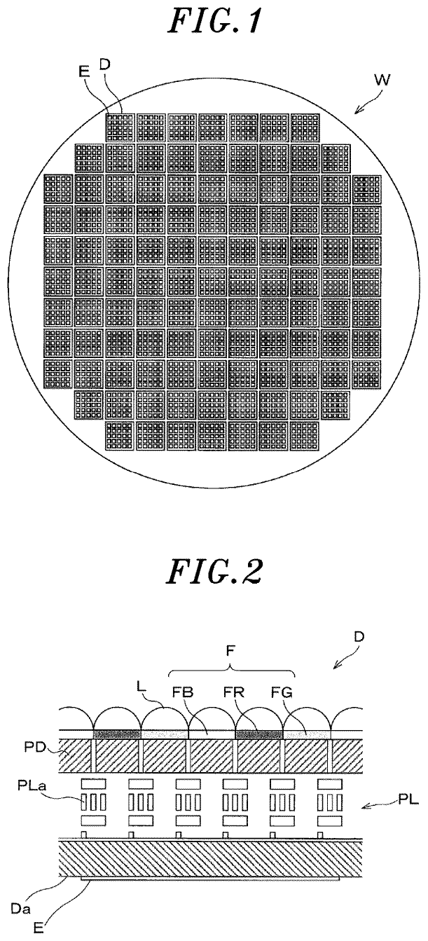

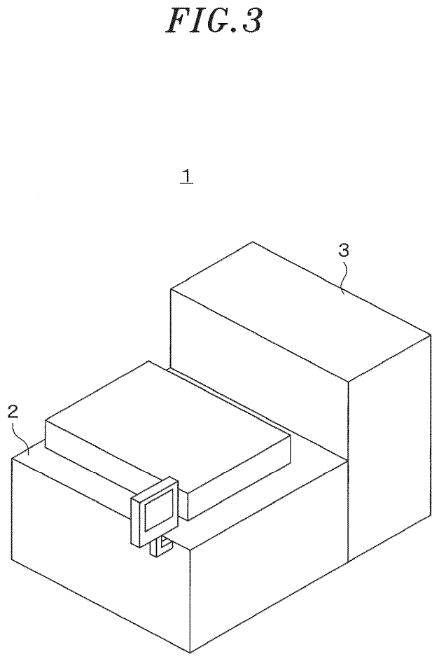

FIG. 1 is a plan view schematically showing a configuration of a substrate as an inspection target object on which a backside-illumination type imaging device is formed, and FIG. 2 is a cross-sectional view schematically showing the configuration of the backside-illumination type imaging device.

As shown in FIG. 1, a plurality of backside-illumination type imaging devices D are formed on a substantially disc-shaped wafer W that is an example of a substrate.

The backside-illumination type imaging device D is a solid-state imaging element, and has a photoelectric conversion part PD, which is a photodiode, and a wiring layer PL including a plurality of wirings PLa, as shown in FIG. 2, for example. Light is incident on the backside-illumination type imaging device D from the backside of the wafer W, which is the surface opposite to the front surface on which the wiring layer PL is provided. Further, the backside-illumination type imaging device D receives the light incident on the backside of the wafer W at the photoelectric conversion part PD via on-chip lenses L and color filters F. The color filters F includes red color filters FR, blue color filters FB, and green color filters FG.

Further, an electrode E is formed on the front (outer) surface Da of the backside-illumination type imaging device D, i.e., the front (outer) surface of the wafer W, and the electrode E is electrically connected to the wiring PLa of the wiring layer PL. The wiring PLa is used for inputting an electric signal to a circuit element in the backside-illumination type imaging device D or outputting an electric signal from the circuit element to the outside of the backside-illumination type imaging device D. The wiring layer PL may include a pixel transistor for controlling a signal related to the photoelectric conversion part.

### FIRST EMBODIMENT

### Inspection Apparatus

Next, an inspection apparatus according to a first embodiment will be described.

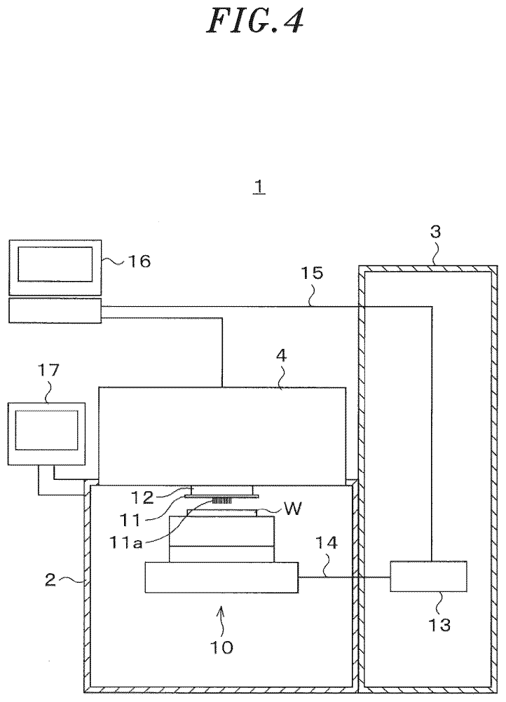

FIGS. 3 and 4 are a perspective view and a front view, respectively, schematically showing a configuration of a prober 1 as an inspection apparatus according to the first embodiment. In FIG. 4, a part of the prober 1 in FIG. 3 is illustrated in cross section to show components in a loader and an accommodation chamber of the prober 1 which will be described later.

The prober 1 inspects electrical characteristics of each of a plurality of backside-illumination type imaging devices D (hereinafter, may be abbreviated as “imaging devices D”) formed on the wafer W. As shown in FIGS. 3 and 4, the prober 1 includes an accommodation chamber 2, a loader 3 disposed adjacent to the accommodation chamber 2, and a tester 4 disposed to cover the accommodation chamber 2.

The accommodation chamber 2 is a hollow housing, and has a stage 10 serving as a placing table. As will be described later, the stage 10 supports the wafer W such that the back surface of the imaging device D faces the stage 10.

Further, the stage 10 is configured to be movable in a horizontal direction and a vertical direction, and the relative positions of a probe card 11 to be described later and the wafer W may be adjusted to bring the electrodes E on the surface of the wafer W into contact with the probes 11a of the probe card 11 to be described later.

Further, the probe card 11 is disposed above the stage 10 in the accommodation chamber 2 to face the stage 10. The probe card 11 has a plurality of needle-shaped probes 11a serving as contact terminals. The probes 11a are formed to be in contact with the corresponding electrodes E on the surface of the wafer W.

The probe card 11 is connected to the tester 4 via an interface 12. In the case of inspecting the imaging devices D, the probes 11a are brought into contact with the corresponding electrodes E, and a power inputted from the tester 4 is supplied to the imaging devices D via the interface 12, or a signal from the imaging devices D is transmitted to the tester 4 via the interface 12.

The loader 3 takes out the wafer W accommodated in a front opening unified pod (FOUP) (not shown), which is a transfer container, and transfers it to the stage 10 of the accommodation chamber 2. Further, the loader 3 receives the wafer W from the stage 10 after the inspection of the electrical characteristics of the imaging device D is completed, and stores it in the FOUP.

The loader 3 has a controller 13 that performs various controls. The controller 13 is a computer having a processor such as a central processing unit (CPU) and a memory, and has a program storage part. The program storage part stores a program that control the operation of individual components of the prober 1 during inspection of electrical characteristics. Further, the program may be recorded in a computer-readable storage medium and installed in the controller 13 from the storage medium. The storage medium may store the program temporarily or non-temporarily.

Further, the controller 13 is connected to the stage 10 via a wiring 14, and is connected to a tester computer 16 via a wiring 15. The controller 13 controls an operation of a light source part (to be described later) of the stage 10 based on an input signal from the tester computer 16. The controller 13 controls a heater 51 which will be described later. Further, the controller 13 may be disposed in the accommodation chamber 2.

The tester 4 has a test board (not shown) that reproduces a part of a circuit configuration of a main board on which the imaging devices D are placed. The test board is connected to the tester computer 16. The tester computer 16 determines whether the imaging devices D are defective or non-defective based on the signal from the imaging devices D. In the tester 4, the circuit configuration of multiple types of main boards can be reproduced by replacing the test board.

Further, the prober 1 includes a user interface part 17. The user interface part 17 is used for displaying information to a user or for allowing a user to input instructions. The user interface part 17 includes a display panel having a touch panel or a keyboard, for example.

In the prober 1 having the above-described individual components, in the case of inspecting electrical characteristics of the imaging devices D, the tester computer 16 transmits data to a test board connected to the imaging devices D via the probes 11a. Further, the tester computer 16 determines whether or not the transmitted data has been correctly processed by the test board based on the electrical signal from the test board.

### Stage 10

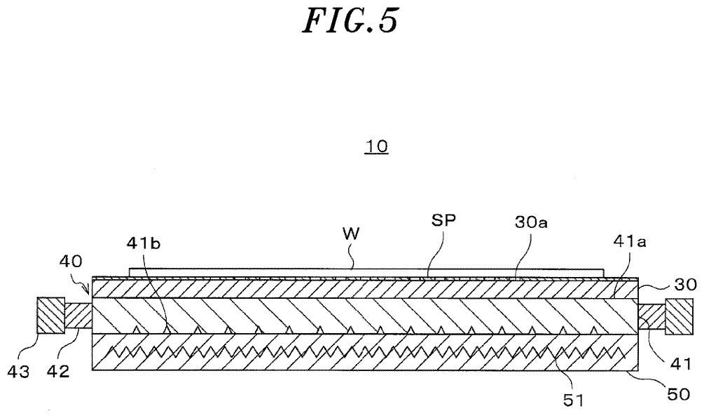

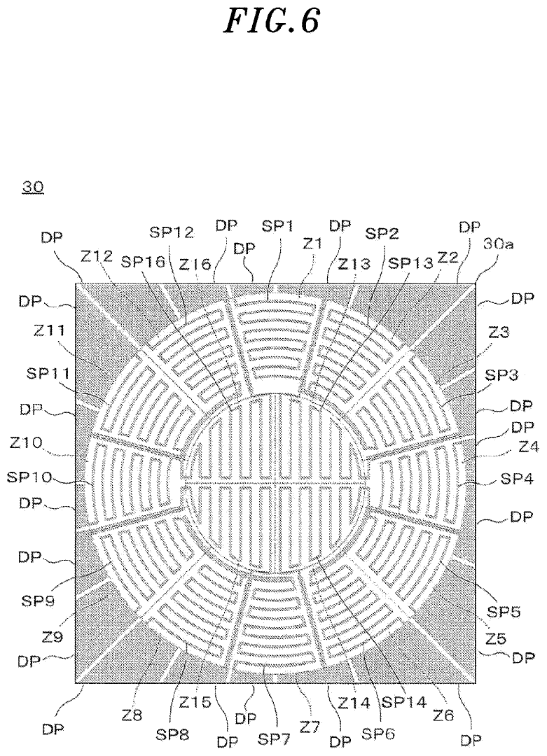

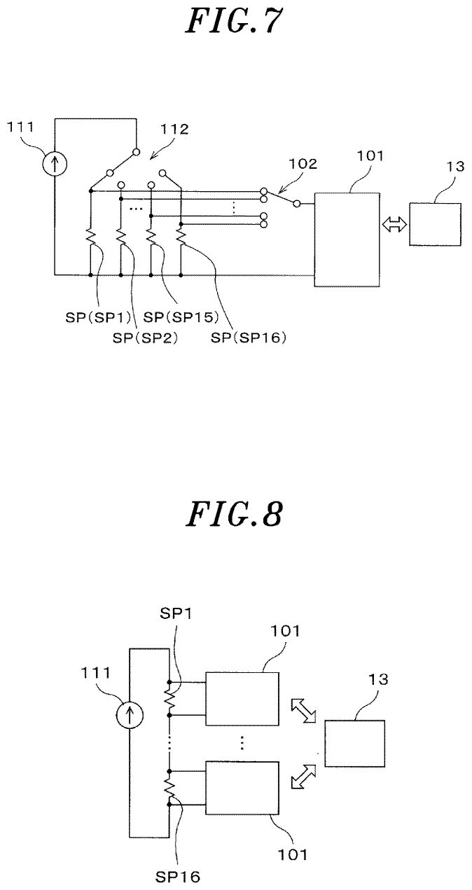

Next, the configuration of the stage 10 will be described. FIG. 5 is a cross-sectional view schematically showing the configuration of the stage 10. FIG. 6 is a top view of a ceiling plate 30 to be described later. FIG. 7 shows a configuration of a circuit for measuring a temperature of a sensor pattern to be described later.

The stage 10 supports the wafer W such that the back surface of the imaging device D faces the stage 10, and as shown in FIG. 5, the stage 10 has the ceiling plate 30, an irradiation part 40, and a base 50.

The ceiling plate 30 is a flat member made of a light transmitting material, and an upper surface 30a thereof serves as the placing surface on which the wafer W is placed. The ceiling plate 30 transmits and diffuses, e.g., the light emitted in a planar shape from the irradiation part 40 toward the wafer W. In other words, the ceiling plate 30 is formed to function as a diffusion plate, for example. Further, the ceiling plate 40 is formed in a square shape with a side length greater than the diameter of the wafer W in plan view, for example.

The configuration of the ceiling plate 30 will be described in detail later.

Further, the above-described “light transmitting material” is a material that transmits light of a wavelength in an inspection range (i.e., light from the irradiation part 40), and is, e.g., glass.

The irradiation part 40 is disposed at a position facing the wafer W on the placing surface 30a with the ceiling plate 30 interposed therebetween, i.e., below the ceiling plate 30, and irradiates light toward the wafer W placed on the placing surface 30a.

The irradiation part 40 has, e.g., a light guiding plate 41 and a light source part 42.

The light guiding plate 41 has a facing surface 41a facing the wafer W on the placing surface 30a with the ceiling plate 30 interposed therebetween, and is, e.g., a member formed in a flat plate shape. The shape and dimensions of the light guiding plate 41 in plan view are the same as those of the ceiling plate 30, for example. Further, the light guiding plate 41 has diffusion dots 41b. The diffusion dots 41b are formed on the surface, i.e., the bottom surface, of the light guiding plate 41 that is opposite to the facing surface 41a, for example. The light guiding plate 41 emits light in a planar shape toward the wafer W as will be described later, and is disposed such that the imaging device forming region of the wafer W is included in the region where the light is emitted in a planar shape in plan view.

Further, a reflection plate (not shown) that reflects light from the light source part 42 may be disposed on the bottom surface of the light guiding plate 41.

The light source part 42 is disposed in a region laterally outside from the light guiding plate 41, and emits light toward the lateral edge surface of the light guiding plate 41. The light source part 42 has, e.g., a plurality of LEDs (not shown) arranged along each side of the light guiding plate 41.

Further, in the present embodiment, a heat dissipation plate 43 is disposed on a back surface of a support (not shown) that supports the LEDs in order to dissipate heat from the LEDs of the light source part 42 to the outside of the stage 10. The heat dissipation plate 43 is made of, e.g., a metal material. The heat dissipation plate 43 may have a passage through which a coolant such as water or the like flows to cool the LEDs of the light source part 42.

In the prober 1, the light emitted from the LEDs of the light source part 42 and incident on the lateral edge surface of the light guiding plate 41 is diffused by the reflection from the diffusion dots 41b, emitted in a planar shape from the facing surface 41a facing the wafer W, and is incident on the imaging devices D of the wafer W while transmitting through the ceiling plate 30.

Further, the LEDs of the light source part 42 emit light including light having a wavelength in the inspection range. The light having a wavelength in the inspection range is, e.g., light having a wavelength in a visible light range, and may be light outside the visible light range, such as infrared light or the like, depending on types of the imaging devices D.

The base 50 is disposed at a position facing the wafer W on the placing surface 30a with the ceiling plate 30 and the light guiding plate 41 interposed therebetween, that is, below the light guiding plate 41, and supports the ceiling plate 30 and the irradiation part 40. For example, the ceiling plate 30 is held by the irradiation part 40 by adhesion using a transparent adhesive material, and the irradiation part 40 is held by the base 50 by adhesion using an adhesive material.

Further, the base 50 is provided with a heater 51 serving as a temperature controller for adjusting the temperatures of the imaging devices D of the wafer W placed on the placing surface 30a. Specifically, the heater 51 adjusts the temperatures of the imaging devices D by heating the wafer W placed on the placing surface 30a. For example, a resistance heater may be used as the heater 51. The heater 51 is controlled by the controller 13.

Further, the amount of heat generated by the heater 51 may be uniform in the upper surface of the base 50. The upper surface of the base 50 may be divided into a plurality of heating regions, and the heater 51 may be provided for each heating region to adjust the amount of heat generated by the heater 51 for each heating region.

In the present embodiment, the wafer W is heated by the heater 51 serving as the temperature controller. However, a device (e.g., a channel for a coolant) that cools the wafer W may be provided instated of or in addition to the heater.

Further, in the stage 10, sensor patterns SP, which are made of a metal material and have a thickness that allows transmission of light, are formed on the placing surface 30a of the ceiling plate 30. Specifically, as shown in FIG. 6, the ceiling plate 30 is divided into a plurality of regions when viewed from above. In the example shown in FIG. 6, the placing surface 30a of the ceiling plate 30 is divided into sixteen regions Z1 to Z16, and sensor patterns SP1 to SP16 are formed in the regions Z1 to Z16, respectively.

The sensor patterns SP may be formed on the opposite surface, i.e., the bottom surface of the ceiling plate 30, instead of being formed on the placing surface 30a of the ceiling plate 30, or in addition to the placing surface 30a of the ceiling plate 30.

The metal material used for the sensor patterns SP contains at least one of silver, copper, or tungsten, for example, and is preferably one whose temperature coefficient a of electrical resistance is about 3.9×10⁻³[1/° C.] within a range of 0° C. to 100° C. Further, as will be described later, when the electrical resistances of the sensor patterns SP are measured, if the electrical resistances of the sensor patterns SP are about 100Ω at room temperature, there is no problem in the measurement accuracy.

The thicknesses of the sensor patterns SP, which are the thicknesses that allow transmission of light, are, e.g., 1/10 or less of the wavelength of the light used for the inspection. If the inspection wavelength is determined, the thickness that allows transmission of light is ½ of the wavelength of the light used for the inspection.

As shown in FIG. 7, the sensor patterns SP are connected to a voltmeter 101 as a measurement part that measures the electrical resistances of the sensor patterns SP. Specifically, the sensor patterns SP1 to SP16 are connected to the voltmeter 101 via, e.g., a switching element 102.

The switching element 102 switches the sensor patterns SP that are electrically connected to the voltmeter 101.

The voltmeter 101 measures the voltage applied to the sensor patterns SP. Specifically, the voltmeter 101 measures a voltage applied to each sensor pattern SP. More specifically, the voltmeter 101 measures a voltage applied to the sensor patterns SP electrically connected to the voltmeter 101 by the switching element 102.

Further, the sensor patterns SP are connected to a current source 111. Specifically, the sensor patterns SP1 to SP16 are connected to the current source 111 via a switching element 112. The switching element 112 switches the sensor patterns SP electrically connected to the current source 111. The current source 111 supplies a DC current of a predetermined magnitude to the sensor patterns SP electrically connected to the current source 111 by the switching element 102.

The voltmeter 101, the current source 111, and the switching elements 102 and 112 are controlled by the controller 13. Further, the measurement result by the voltmeter 101 is outputted to the controller 13.

The controller 13 calculates the temperatures of the sensor patterns SP as the temperatures of the imaging devices D based on the measurement results of the sensor patterns SP by the voltmeter 101. Specifically, the controller 13 calculates the temperatures of the sensor patterns SP as the temperatures of the imaging devices D based on the measurement results of the sensor patterns SP by the voltmeter 101 in the regions corresponding to the imaging devices D among the plurality of regions Z1 to Z16 of the placing surface 30a.

The following is description of a method of calculating the temperatures of the sensor patterns SP from the measurement results of the sensor patterns SP by the voltmeter 101 (specifically, the measurement of the voltage applied to the sensor patterns SP), for example. In other words, first, the electrical resistances of the sensor patterns SP are calculated from the measurement result of the voltage applied to the sensor patterns SP and the current (current value) supplied from the current source 111. Further, the temperatures of the sensor patterns SP are calculated from the calculated electrical resistances of the sensor patterns SP using a previously acquired relational equation between the electrical resistance and the temperature.

Information required for calculating the temperature is stored in advance in a storage part (not shown).

Further, the above-described relational equation is stored in advance for each sensor pattern SP, and the above-described relational equation for a specific sensor pattern SP is used for calculating the temperatures of the specific sensor pattern SP.

As described above, the sensor patterns SP are connected to the voltmeter 101 or the current source 111. The sensor patterns SP are connected to the voltmeter 101 or the like via electrode patterns DP disposed outside the sensor patterns SP in plan view, as shown in FIG. 6, for example.

The sensor patterns SP are formed in regions that overlap the wafer W in plan view (specifically, regions that overlap a portion of the wafer W where the imaging devices are formed), whereas the electrode patterns DP are disposed in the outer region thereof.

Further, the sensor patterns SP are formed to be narrow, whereas the electrode patterns DP are formed to be wide. Specifically, the sensor patterns SP have a narrow and meandering pattern, whereas the electrode patterns DP have a film-shaped pattern formed over the entire region.

The thickness and material of the electrode patterns DP are the same as those of the sensor patterns SP, for example, but may be different therefrom. However, when they are the same, the electrode patterns DP and the sensor patterns SP can be formed simultaneously by sputtering or the like.

The electrode patterns DP may be partially shared between the sensor patterns SP, as long as the electrical resistances of the sensor patterns SP can be measured independently.

### Inspection Process

Next, an example of an inspection process for a wafer W using the prober 1 will be described. In the following description, one imaging device D is inspected by one inspection process. However, a plurality of imaging devices D may be inspected collectively by one inspection process using the prober 1. Further, the following inspection process is performed under the control of the controller 13.

For example, first, the wafer W is taken out of the FOUP of the loader 3 and transferred into the accommodation chamber 2. Then, the wafer W is placed on the placing surface 30a of the ceiling plate 30 of the stage 10 where the sensor patterns SP are formed, so that the back surfaces of the imaging devices D formed on the wafer W face the stage 10 and the wafer W and the stage 10 are brought into contact with each other.

Then, the stage 10 is moved, and the probes 11a provided above the stage 10 are brought into contact with the electrodes E of the imaging devices D to be inspected.

Then, light is irradiated from the irradiation part 40. Specifically, all the LEDs of the light source part 42 are turned on. Accordingly, light is incident on the lateral edge surface of the light guiding plate 41 from each LED. The light incident on the light guiding plate 41 is reflected and diffused toward the ceiling plate 30 by the diffusion dots 41b, and is emitted in a planar shape from the facing surface 41a of the light guiding plate 41 that faces the wafer W.

The light emitted from the light guiding plate 41 is diffused by the ceiling plate 30, transmits through the ceiling plate 30, and is incident on the wafer W.

When the light is irradiated, an inspection signal is inputted to the probes 11a. Accordingly, the inspection of the imaging devices D is performed.

During the inspection, the voltmeter 101 measures the voltage applied to the sensor patterns SP, and the controller 13 calculates the temperatures of the sensor patterns SP as the temperatures of the imaging devices D based on the measurement result by the voltmeter 101. Specifically, the controller 13 specifies a region closest to the center position of the imaging device D to be inspected among the plurality of regions Z1 to Z16 on the placing surface 30a, and the voltmeter 101 measures the voltage applied to the sensor patterns SP formed in that region. Further, the controller 13 calculates the temperatures of the sensor patterns SP formed in the region closest to the center positions of the imaging devices D as the temperature of the imaging devices D to be inspected based on the measurement result by the voltmeter 101.

Then, during the inspection, the controller 13 controls the heater 51 based on the temperature calculation result. Specifically, during the inspection, for example, the controller 13 controls the heater 51 based on the temperature calculation result such that the temperatures of the sensor patterns SP, i.e., the temperatures of the imaging devices D to be inspected, are maintained at a target temperature T.

Then, the same processes are repeated until the inspection of all the imaging devices D is completed.

### Main Effects of Present Embodiment

As described above, in the present embodiment, the stage 10 has the ceiling plate 30 having the placing surface 30a on which the wafer W is placed, the irradiation part 40 that is disposed at a position facing the wafer W with the ceiling plate 30 interposed therebetween and irradiates light toward the wafer W placed on the placing surface 30a, and the heater 51 that adjusts the temperature of the imaging devices D of the wafer W placed on the placing surface 30a. The ceiling plate 30 has the sensor patterns SP made of a metal material and having a thickness that transmits light formed on at least one of the placing surface 30a of the ceiling plate 30 or the opposite surface thereof. Therefore, if the electrical resistances of the sensor patterns SP are measured, the temperatures of the sensor patterns SP can be calculated as the temperatures of the imaging devices D based on the measurement result. Since the sensor patterns SP are formed on the ceiling plate 30 and the sensor patterns SP and the wafer W are close to each other, the temperatures of the sensor patterns SP and the temperature of the wafer W, i.e., the temperatures of the imaging devices D, are substantially the same. In other words, in accordance with the present embodiment, the temperatures of the imaging devices D can be accurately detected. Further, since the sensor patterns SP are formed to have a thickness that transmits light, the sensor patterns SP do not block the inspection light directed toward the wafer W through the ceiling plate 30. In this manner, in accordance with the present embodiment, the temperatures of the imaging devices D can be accurately detected without adversely affecting the light irradiated to the imaging devices D.

Further, when the sensor patterns SP are formed on the placing surface 30a of the ceiling plate 30, the wafer W is placed on the sensor patterns SP, and the sensor patterns SP and the wafer W become closer to each other, so that the temperatures of the imaging devices D can be more accurately measured based on the measurement results of the electrical resistances of the sensor patterns SP. Further, when the sensor patterns SP are formed on the placing surface 30a of the ceiling plate 30, the above-described effects can be obtained regardless of the material of the ceiling plate 30 (specifically, the base material of the ceiling plate 30). In other words, regardless of the material of the ceiling plate 30, the temperatures of the imaging devices D can be detected more accurately without adversely affecting the light irradiated to the imaging devices D.

Further, since the temperatures of the imaging devices can be detected accurately as described above, the temperatures of the imaging devices can be maintained at a desired temperature by controlling the heater 51 based on the detection result.

Further, in the present embodiment, the sensor patterns SP are connected to the voltmeter 101 or the like via the electrode patterns DP. The electrode patterns DP are formed in the outer region of the region overlapping the imaging devices D in plan view, and are formed to be wider than the sensor patterns SP, which facilitates the operation of connecting the sensor patterns SP to the voltmeter 101 (for example, the operation of connecting the terminal of the wiring to the electrode patterns DP). Further, since the electrode patterns DP are formed to be wider than the sensor patterns SP, it is possible to suppress the influence of the electrical resistances of the electrode patterns DP on the measurement result of the electrical resistances of the sensor patterns SP by the voltmeter 101. Therefore, the temperatures of the imaging devices D can be detected more accurately.

### Another Example of Connection of Sensor Patterns SP

FIG. 8 shows another example of the connection between the sensor patterns SP and the current source 111.

In the above example, all the sensor patterns SP1 to SP16 are connected to the common voltmeter 101. Instead, here, the sensor patterns SP1 to SP16 may be divided into a plurality of groups, and the voltmeter 101 may be provided for each group. In this case, a different current source 111 may be provided for each group, or the current source 111 may be common to all the groups.

Further, as shown in FIG. 8, the sensor patterns SP1 to SP16 may be connected in series to the current source 111. In this case, the voltmeter 101 is provided for each sensor pattern SP, for example.

Further, the sensor patterns SP1 to SP16 may be divided into a plurality of groups, and the sensor patterns SP belonging to the same group may be connected in series to the current source 111. In this case, a different current source 111 may be provided for each group, or the current source 111 may be common to all the groups and a plurality of groups may be connected in parallel to the current source.

### SECOND EMBODIMENT

### Stage 10A

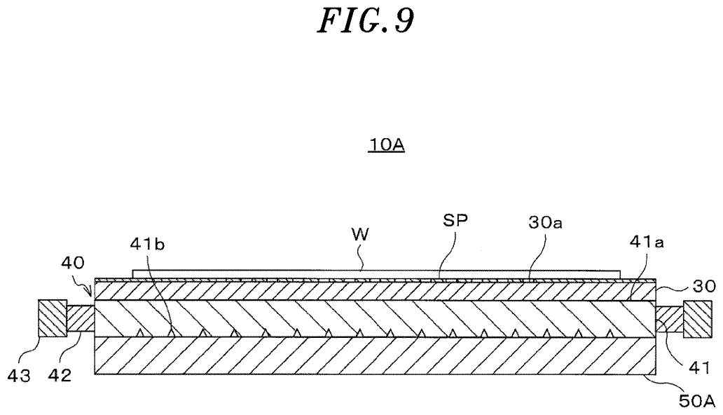

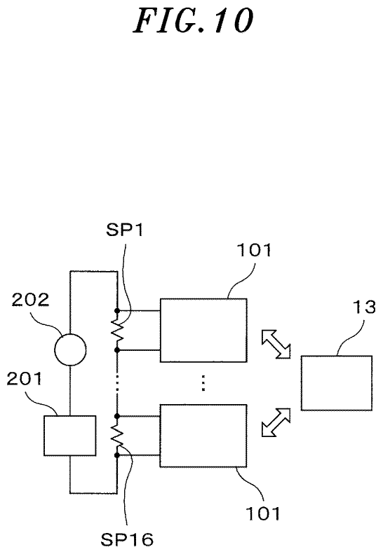

FIG. 9 is a cross-sectional view schematically showing a configuration of a stage 10A of a prober as an inspection apparatus according to a second embodiment. FIG. 10 shows a configuration of a circuit related to the sensor patterns SP.

In the first embodiment, the heater 51 is disposed in the base 50. On the other hand, in the present embodiment, as shown in FIG. 9, no heater is disposed in the base 50A. Instead, the sensor patterns SP are configured to serve as a heater.

Further, in the present embodiment, the sensor patterns SP are connected to a voltage regulator 201 that adjusts the voltage applied to the sensor patterns SP, as shown in FIG. 10. Specifically, for example, the sensor patterns SP1 to SP16 are connected in series to the voltage regulator 201.

In addition, in the present embodiment, an ammeter 202 for measuring a current flowing through the sensor patterns SP1 to SP16 is provided.

The voltage regulator 201 and the ammeter 202 are controlled by the controller 13. The measurement result by the ammeter 202 is outputted to the controller 13.

In the present embodiment, as in the first embodiment, the voltage applied to the sensor patterns SP is measured by the voltmeter 101. In the present embodiment, the current flowing through the sensor patterns SP is measured by the ammeter 202. In the present embodiment, the electrical resistances of the sensor patterns SP are calculated by the controller 13 from the measurement result by the voltmeter 101 and the measurement result by the ammeter 202. Then, the temperatures of the sensor patterns SP are calculated from the calculated electrical resistances of the sensor patterns SP using a previously acquired relational equation between an electrical resistance and a temperature.

In addition, in the present embodiment, the controller 13 controls the voltage regulator 201 based on the calculated temperatures of the sensor patterns SP, and adjusts the voltage applied to the sensor patterns SP serving as a heater. Accordingly, the temperatures of the sensor patterns SP, i.e., the temperatures of the imaging devices D to be inspected, can be maintained at the target temperature T.

Further, even when the sensor patterns SP serve as a heater as in the present embodiment, the heater 51 in FIG. 5 may be provided.

### Modification of Irradiation Part

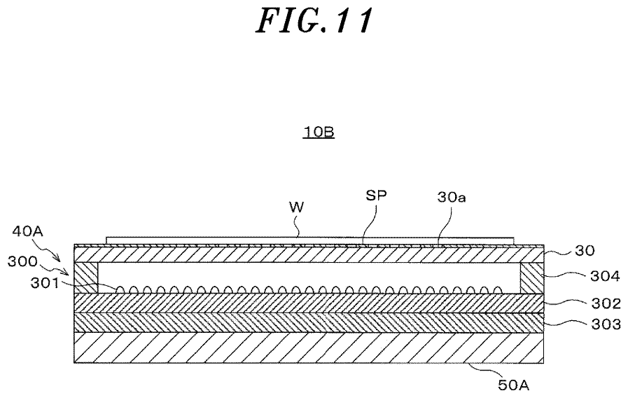

FIG. 11 shows another example of the irradiation part.

An irradiation part 40A shown in FIG. 11 is disposed at a position facing the wafer W with the ceiling plate 30 interposed therebetween, and has a light source part 300 that emits light toward the ceiling plate 30, i.e., toward the wafer W.

The light source part 300 has a plurality of light emitting diodes (LEDs) 301 as light sources, a substrate 302, and a heat dissipation plate 303.

Each of the LEDs 301 is directed toward the wafer W and emits light of a wavelength in an inspection range.

Further, in plan view, the LEDs 301 are arranged in a region (hereinafter, referred to as “LED forming region”) that overlaps the wafer W placed on the stage 10, and the size of the LED forming region is substantially the same as that of the wafer W. The LEDs 301 are arranged at equal intervals in the LED forming region.

The light emission intensity of the LEDs 301 is adjusted for each LED 301, for example. The LED forming region may be divided into a plurality of regions, and the light emission intensity of the LEDs 301 may be adjusted for each region.

The substrate 302 holds the LEDs 301, and has a wiring pattern (not shown) for controlling the LEDs 301.

The heat dissipation plate 303 dissipates heat from the LEDs 301 to the outside of the stage 10B, and is made of, e.g., a metal material. The heat dissipation plate 303 may have a channel through which a coolant such as water or the like flows to cool the LEDs 301.

In this example, the ceiling plate 30 may not function as a diffusion plate.

By using the irradiation part 40A of this example, it is possible to irradiate the imaging device D to be inspected with inspection light having an intensity closer to a desired value, compared to the above-described irradiation part 40. Further, although it may be considered to use the irradiation part 40A of FIG. 11 instead of the irradiation part 40 in the stage 10 of FIG. 5, the LED 301 of the irradiation part 40A are affected by the heat from the heater 51, which make it difficult to set the intensity of the light irradiated to the wafer W to a desired value. In the example of FIG. 11, the sensor patterns SP function as a heater, so that the LED 301 of the irradiation part 40A is less affected by the sensor patterns SP as a heater.

### THIRD EMBODIMENT

### Stage 10C

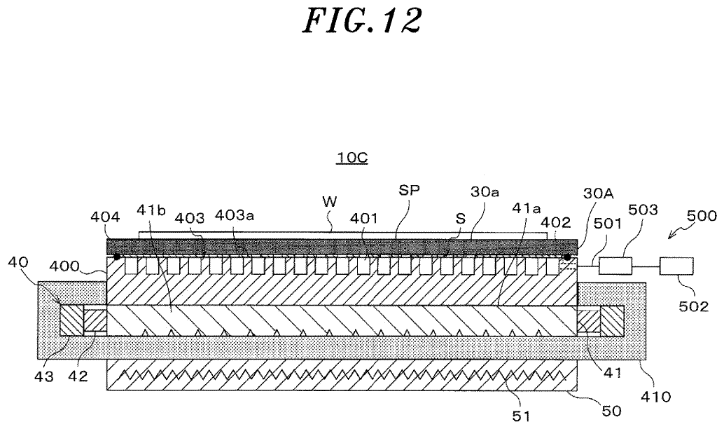

FIG. 12 is a cross-sectional view schematically showing a configuration of a stage 10C of a prober as an inspection apparatus according to a third embodiment.

The stage 10C in FIG. 12 has a ceiling plate 30A, a base member 400, and a frame 410 in addition to the irradiation part 40 and the base 50.

The ceiling plate 30A has the sensor patterns SP formed thereon, similarly to the ceiling plate 30 shown in FIG. 5 and the like. Specifically, the ceiling plate 30A has the sensor patterns SP formed on the bottom surface that is the surface opposite the placing surface 30a.

However, unlike the ceiling plate 30 shown in FIG. 5 and the like, the ceiling plate 30A is made of light transmitting porous glass having an average pore size of 30 nm or less. Specifically, the porous glass used for the ceiling plate 30A is porous glass obtained as follows. In other words, first, raw glass (e.g., Na₂O—B₂O₃—SiO₂ glass) is melted, and then phase-separated by heat treatment or the like, so that a mesh made of another phase (Na₂O—B₂O₃ glass) is formed in a flat plate made of one phase (SiO₂ glass). Then, only the mesh is removed by acid treatment or the like, so that porous glass in which a plurality of holes penetrate through a flat plate made of the one phase (SiO₂ glass) nonlinearly in a thickness direction is obtained. This porous glass is used for the ceiling plate 30A.

Since the ceiling plate 30A is made of the porous glass described above, holes penetrating through the ceiling plate 30A nonlinearly in the thickness direction are formed not only in the region that does not overlap the imaging devices D but also in the region that overlaps the imaging devices D in plan view when the wafer W is placed on the ceiling plate 30A. In other words, the holes penetrating through the ceiling plate 30A nonlinearly in the thickness direction are formed in the entire surface of the ceiling plate 30A.

The base member 400 is made of a light transmitting material, and is disposed between the ceiling plate 30A and the irradiation part 40. The base member 400 is a member that forms a space S between the ceiling plate 30A and the base member. Specifically, the light transmitting material used for the base member 400 is glass having a thermal expansion coefficient that is substantially the same as that of the wafer W.

For example, a recess 401 that is recessed toward the side opposite to the ceiling plate 30A is formed at the center of the base member 400, and the space S is formed by blocking the opening of the recess 401 by the ceiling plate 30A. The space S is evacuated by an exhaust mechanism 500.

The exhaust mechanism 500 is controlled by the controller 13, and has an exhaust line 501 in addition to a vacuum exhaust pump 502. One end of the exhaust line 501 is connected to the space S via a connection hole 402, and the other end thereof is connected to the vacuum exhaust pump 502. A buffer tank 503 is interposed in the exhaust line 501. The exhaust lines 501 must be designed to have a low conductance so that the buffer tank 503 becomes substantially the same space.

Further, a support portion 403 that extends from the bottom portion of the recess 401 toward the ceiling plate 30A and supports the ceiling plate 30A is disposed in the recess 401. The support portion 403 has a plurality of support columns 403a formed in a columnar shape and extending toward the ceiling plate 30A, for example. The support portion 403 may have a support wall formed in a spiral shape in plan view, instead of the support columns 403a. The support portion 403 may have both the support columns 403a and the spiral-shaped support wall.

In order to make the space S airtight, an O-ring 404 is disposed between the ceiling plate 30A and the base member 400, for example. Specifically, the O-ring 404 is disposed between the peripheral portion of the ceiling plate 30A and the peripheral portion of the base member 400. The ceiling plate 30A and the base member 400 may be bonded by an adhesive.

The frame 410 holds the irradiation part 40, which holds the base member 400, by bonding using an adhesive, for example. The frame 410 is also held by the base 50 by bonding using an adhesive, for example.

### Inspection Process

In an inspection process for the wafer W using the prober having the stage 10C, when the wafer W is placed on the placing surface 10a of the ceiling plate 30A of the stage 10C, the space S between the ceiling plate 30C and the base member 400 is evacuated by the exhaust mechanism 500. Since the ceiling plate 30A is made of porous glass, the space between the backside of the wafer W and the ceiling plate 30A is evacuated through the holes in the porous glass of the ceiling plate 30A by evacuating the space S as described above, and the wafer W is attracted to and held by ceiling plate 30A.

In the present embodiment, the ceiling plate 30A is made of porous glass, and the holes for attracting the wafer W are formed in the entire surface of the ceiling plate 30A that includes the region overlapping the imaging devices D in plan view. Therefore, even if the exhaust flow rate from the space S between the ceiling plate 30A and the base member 400 is low, the wafer W can be attracted to the ceiling plate 30A with a vacuum attracting force higher than that in the case where the holes for attracting the wafer W are formed only in a region that does not overlap the imaging devices D in plan view. That is, in accordance with the present embodiment, the wafer W can be appropriately attracted.

Further, since the exhaust mechanism 500 has the buffer tank 503, the exhaust flow through the connection hole 402 can be reduced, and the increase in the attracting force of the wafer W only in the vicinity of the connection hole 402 can be prevented.

Further, in the above inspection process, light is irradiated from the irradiation part 40. Specifically, all the LEDs of the light source part 42 are turned on, and the light is emitted in a planar shape from the surface of the light guiding plate 41 that faces the wafer W. The light emitted from the light guiding plate 41 is incident on the wafer W through the base member 400 and the ceiling plate 30A.

Unlike the present embodiment, if the diameter of the hole penetrating through the ceiling plate 30A non-linearly is the same as the wavelength of the light irradiated from the irradiation part 40, the light is refracted or reflected by the hole and, thus, the light incident on the wafer W through the ceiling plate 30A is locally intensified or weakened. In this case, the light irradiated from the irradiation part 40 may not be incident with a desired intensity on a desired portion of the wafer W (specifically, portion corresponding to the imaging device D to be inspected). On the other hand, in the present embodiment, the diameter (average hole diameter) of the hole penetrating through the ceiling plate 30A non-linearly is 30 nm or less, which is sufficiently small compared to the wavelength of the light irradiated from the irradiation part 40, so that the existence of the hole is substantially ignored. Therefore, in the present embodiment, the light is not refracted or reflected by the hole. Accordingly, in accordance with the present embodiment, if the light incident on the ceiling plate 30A is not deflected in the plane, the light incident on the wafer W through the ceiling plate 30A is not deflected in the plane. Hence, in the present embodiment, the light irradiated from the irradiation part 40 can be incident with a desired intensity on a desired portion of the wafer W (specifically, portion corresponding to the imaging device D to be inspected).

### Another Example of Porous Glass Constituting Ceiling Plate 30A

In the above example, the porous glass forming the ceiling plate 30 has an average pore diameter of 30 nm or less and has a light transmitting property, but it may have an average pore diameter of 10 μm or more and have a light transmitting property. The porous glass having an average pore diameter of 10 μm or more and having a light transmitting property can be obtained in the same manner as the porous glass having an average pore diameter of 30 nm or less and having a light transmitting property.

Even in the case of using light transmitting porous glass having an average pore diameter of 10 um or more, the holes penetrating through the ceiling plate 30A nonlinearly in the thickness direction are formed in the ceiling plate 30A in the region that does not overlap the imaging devices D in plan view and the region that overlaps the imaging devices D in a state where the wafer W is placed on the ceiling plate 30A. In other words, the holes penetrating through the ceiling plate 30A nonlinearly in the thickness direction are formed on the entire surface of the ceiling plate 30A. Therefore, in this example, even if the exhaust flow rate from the space S between the ceiling plate 30A and the base member 400 is low, the wafer W can be attracted to the ceiling plate 30 with a high vacuum attracting force.

Further, in this example, the diameter (average pore diameter) of the holes penetrating through the ceiling plate 30A nonlinearly is 10 μm or more, which is sufficiently greater than the wavelength of the light irradiated from the irradiation part 40 and incident on the ceiling plate 30A. In addition, the holes have various shapes. Therefore, even if the light incident on the ceiling plate 30A is refracted or reflected by the holes, the light incident on the wafer W through the ceiling plate 30A is not regularly intensified or weakened. In this example, the light incident on the ceiling plate 30A is diffused by the ceiling plate 30A and incident on the wafer W. Hence, in this example, if the light incident on the ceiling plate 30A is not deflected in the plane, the light incident on the wafer W through the ceiling plate 30A is not be deflected in the plane, and the light incident on the wafer W through the ceiling plate 30A becomes more uniform in the plane compared to the light incident on the ceiling plate 30A. Therefore, in this example, the light irradiated from the irradiation part 40 can be incident on a desired portion (specifically, a portion corresponding to the imaging device D to be inspected) on the wafer W with a desired intensity.

### Another Example of Ceiling Plate 30A

In the example of FIG. 12, the sensor patterns SP are formed on the bottom surface of the ceiling plate 30A made of porous glass. Alternatively or additionally, the sensor patterns SP may be formed on the upper surface of the ceiling plate 30A, i.e., the placing surface 30a.

Further, the placing surface 30a of the ceiling plate 30A may be coated with silicon. Specifically, the placing surface 30a of the ceiling plate 30A may be coated with silicon in a state where the holes of the porous glass constituting the ceiling plate 30A are not blocked.

The following is description of a method for manufacturing the ceiling plate 30A coated with silicon in a state where the holes are not blocked, for example. In other words, after the entire surface of the porous glass is coated with silicon, a gas is blown, before the silicon solidifies, toward the back surface thereof to blow away a portion of silicon overlapping the holes of the ceiling plate 30A among the entire surface of the porous glass. Accordingly, it is possible to manufacture the ceiling plate 30A coated with silicon in a state where the holes are not blocked.

In this example, when the wafer W is attracted and held on the ceiling plate 30A through the holes in the porous glass constituting the ceiling plate 30A, the silicon coating layer is actually brought into contact with the ceiling plate 30A even if the backside (specifically, the on-chip lens L) of the wafer W is brought into contact with. Therefore, it is possible to prevent the backside (specifically, the on-chip lens L) of the wafer W from being damaged by the contact with the ceiling plate 30A.

Further, both the silicon coating layer and the sensor patterns SP may be formed on the placing surface 30a of the ceiling plate 30A.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

The effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

The following configurations are also included in the technical scope of the present disclosure.

### Appendix 1

An inspection apparatus for inspecting an inspection target device, wherein the inspection target device is a backside-illumination type imaging device on which light is incident from a back surface opposite to a side on which a wiring layer is provided, and is formed on an inspection target object,
the inspection apparatus comprising a placing table that supports the inspection target object while facing the back surface of the imaging device, and
the placing table includes:
a ceiling plate made of a light transmitting material and having a placing surface on which the inspection target object is placed,
an irradiation part that is disposed at a position facing the inspection target object with the ceiling plate interposed therebetween and that irradiates light toward the inspection target object placed on the placing surface; and
a temperature controller configured to adjusts a temperature of the inspection target device of the inspection target object placed on the placing surface,
wherein a pattern made of a metal material and having a thickness that transmits light is formed on at least one of the placing surface of the ceiling plate or a surface opposite to the placing surface.

### Appendix 2

The inspection apparatus of appendix 1, further comprising:
a measurement part configured to measure an electrical resistance of the pattern, and
a controller,
wherein the controller calculates a temperature of the pattern as a temperature of the device to be inspected based on a measurement result of the measurement part.

### Appendix 3

The inspection apparatus of appendix 2, wherein the controller controls the temperature controller based on a calculation result of the temperature of the pattern.

### Appendix 4

The inspection apparatus of appendix 1, wherein the ceiling plate is divided into a plurality of regions, and
the pattern is formed in each of the plurality of regions.

### Appendix 5

The inspection apparatus of appendix 4, further comprising:
a measurement part configured to measures an electrical resistance of each pattern, and
a controller,
wherein the controller calculates a temperature of the pattern as a temperature of the inspection target device based on a measurement result of the measurement part for the pattern in a region corresponding to the inspection target device among the plurality of regions.

### Appendix 6

The inspection apparatus of appendix 5, wherein the controller controls the temperature controller based on a calculation result of the temperature of the pattern.

### Appendix 7

The inspection apparatus of any one of appendices 2, 3, 5, and 6, wherein the pattern is formed in a region overlapping the inspection target device in plan view, and is connected to the measurement part via another pattern formed in an outer region of the region, and the other pattern is formed to be wider than the pattern.

### Appendix 8

The inspection apparatus of any one of appendices 1 to 7, in which the temperature controller has a heater configured to heat the inspection target device of the inspection target object placed on the placing surface, and the pattern serves as the heater.

### Appendix 9

The inspection apparatus of any one of appendices 1 to 8, wherein the irradiation part includes:
a light guiding plate having a facing surface facing the inspection target object with the ceiling plate interposed therebetween, and
a light source part that is disposed in a region laterally outside from the light guiding plate and emits light toward a lateral edge surface of the light guiding plate,
wherein the light guiding plate reflects light emitted from the light source part and incident on the lateral edge surface of the light guiding plate toward the facing surface and emits light in a planar shape from the facing surface.

### Appendix 10

The inspection apparatus of appendix 9, wherein the temperature controller is disposed at a position facing the inspection target object with the ceiling plate and the light guiding plate interposed therebetween.

### Appendix 11

The inspection apparatus of appendix 8, wherein the irradiation part includes a light source part that is disposed at a position facing the inspection target object with the ceiling plate interposed therebetween and emits light toward the ceiling plate.

### Appendix 12

The inspection apparatus of any one of appendices 1 to 11, wherein the placing table further includes a base member that is made of a light transmitting material, disposed between the ceiling plate and the irradiation part, and forms an exhaust space between the ceiling plate and the base member, and the ceiling plate is made of porous glass having an average pore size of 30 nm or less or 10 μm or more.

### Appendix 13

A placing table for an inspection apparatus for inspecting an inspection target device,
wherein the inspection target device is a backside-illumination type imaging device on which light is incident from the back surface opposite to a side on which a wiring layer is provided, and is formed on an inspection target object, and
the placing table supports the inspection target object while facing the back surface of the imaging device, and includes:
a ceiling plate made of a light transmitting material and having a placing surface on which the inspection target object is placed;
an irradiation part that is disposed at a position facing the inspection target object with the ceiling plate interposed therebetween and irradiates light toward the inspection target object placed on the placing surface; and
a temperature controller configured to adjust a temperature of the inspection target device of the inspection target object placed on the placing surface,
wherein a pattern made of a metal material and having a thickness that transmits light is formed on the placing surface of the ceiling plate.

1. An inspection apparatus for inspecting an inspection target device,
wherein the inspection target device is a backside-illumination type imaging device on which light is incident from a back surface opposite to a side on which a wiring layer is provided, and is formed on an inspection target object,
the inspection apparatus comprising:
a placing table that supports the inspection target object while facing the back surface of the imaging device,
the placing table includes:
a ceiling plate made of a light transmitting material and having a placing surface on which the inspection target object is placed,
an irradiation part that is disposed at a position facing the inspection target object with the ceiling plate interposed therebetween and that irradiates light toward the inspection target object placed on the placing surface; and
a temperature controller configured to adjusts a temperature of the inspection target device of the inspection target object placed on the placing surface,
wherein a pattern made of a metal material and having a thickness that transmits light is formed on at least one of the placing surface of the ceiling plate or a surface opposite to the placing surface.

2. The inspection apparatus of claim 1, further comprising:
a measurement part configured to measure an electrical resistance of the pattern, and
a controller,
wherein the controller calculates a temperature of the pattern as a temperature of the device to be inspected based on a measurement result of the measurement part.

3. The inspection apparatus of claim 2, wherein the controller controls the temperature controller based on a calculation result of the temperature of the pattern.

4. The inspection apparatus of claim 1, wherein the ceiling plate is divided into a plurality of regions, and
the pattern is formed in each of the plurality of regions.

5. The inspection apparatus of claim 4, further comprising:
a measurement part configured to measures an electrical resistance of each pattern, and
a controller,
wherein the controller calculates a temperature of the pattern as a temperature of the inspection target device based on a measurement result of the measurement part for the pattern in a region corresponding to the inspection target device among the plurality of regions.

6. The inspection apparatus of claim 5, wherein the controller controls the temperature controller based on a calculation result of the temperature of the pattern.

7. The inspection apparatus of claim 2, wherein the pattern is formed in a region overlapping the inspection target device in plan view, and is connected to the measurement part via another pattern formed in an outer region of the region, and
the other pattern is formed to be wider than the pattern.

8. The inspection apparatus of claim 3, wherein the pattern is formed in a region overlapping the inspection target device in plan view, and is connected to the measurement part via another pattern formed in an outer region of the region, and
the other pattern is formed to be wider than the pattern.

9. The inspection apparatus of claim 5, wherein the pattern is formed in a region overlapping the inspection target device in plan view, and is connected to the measurement part via another pattern formed in an outer region of the region, and
the other pattern is formed to be wider than the pattern.

10. The inspection apparatus of claim 1, in which the temperature controller has a heater configured to heat the inspection target device of the inspection target object placed on the placing surface, and
the pattern serves as the heater.

11. The inspection apparatus of claim 2, in which the temperature controller has a heater configured to heat the inspection target device of the inspection target object placed on the placing surface, and
the pattern serves as the heater.

12. The inspection apparatus of claim 1, wherein the irradiation part includes:
a light guiding plate having a facing surface facing the inspection target object with the ceiling plate interposed therebetween, and
a light source part that is disposed in a region laterally outside from the light guiding plate and emits light toward a lateral edge surface of the light guiding plate,
wherein the light guiding plate reflects light emitted from the light source part and incident on the lateral edge surface of the light guiding plate toward the facing surface and emits light in a planar shape from the facing surface.

13. The inspection apparatus of claim 2, wherein the irradiation part includes:
a light guiding plate having a facing surface facing the inspection target object with the ceiling plate interposed therebetween, and
a light source part that is disposed in a region laterally outside from the light guiding plate and emits light toward a lateral edge surface of the light guiding plate,
wherein the light guiding plate reflects light emitted from the light source part and incident on the lateral edge surface of the light guiding plate toward the facing surface and emits light in a planar shape from the facing surface.

14. The inspection apparatus of claim 12, wherein the temperature controller is disposed at a position facing the inspection target object with the ceiling plate and the light guiding plate interposed therebetween.

15. The inspection apparatus of claim 13, wherein the temperature controller is disposed at a position facing the inspection target object with the ceiling plate and the light guiding plate interposed therebetween.

16. The inspection apparatus of claim 10, wherein the irradiation part includes a light source part that is disposed at a position facing the inspection target object with the ceiling plate interposed therebetween and emits light toward the ceiling plate.

17. The inspection apparatus of claim 11, wherein the irradiation part includes a light source part that is disposed at a position facing the inspection target object with the ceiling plate interposed therebetween and emits light toward the ceiling plate.

18. The inspection apparatus of claim 1, wherein the placing table further includes a base member that is made of a light transmitting material, disposed between the ceiling plate and the irradiation part, and forms an exhaust space between the ceiling plate and the base member, and
the ceiling plate is made of porous glass having an average pore size of 30 nm or less or 10 μm or more.

19. The inspection apparatus of claim 2, wherein the placing table further includes a base member that is made of a light transmitting material, disposed between the ceiling plate and the irradiation part, and forms an exhaust space between the ceiling plate and the base member, and
the ceiling plate is made of porous glass having an average pore size of 30 nm or less or 10 μm or more.

20. A placing table for an inspection apparatus for inspecting an inspection target device,
wherein the inspection target device is a backside-illumination type imaging device on which light is incident from the back surface opposite to a side on which a wiring layer is provided, and is formed on an inspection target object, and
the placing table supports the inspection target object while facing the back surface of the imaging device, and includes:
a ceiling plate made of a light transmitting material and having a placing surface on which the inspection target object is placed;
an irradiation part that is disposed at a position facing the inspection target object with the ceiling plate interposed therebetween and irradiates light toward the inspection target object placed on the placing surface; and
a temperature controller configured to adjust a temperature of the inspection target device of the inspection target object placed on the placing surface,
wherein a pattern made of a metal material and having a thickness that transmits light is formed on the placing surface of the ceiling plate.
